(19) United States
(12) Patent Application Publication
(10) Pub. No.: US 2025/0241157 A1
(43) Pub. Date: Jul. 24, 2025

(54) FLEXIBLE DISPLAY DEVICE

(71) Applicant: LG Display Co., Ltd., Seoul (KR)

(72) Inventors: Sueon Lee, Paju-si (KR); JunYoung Kwon, Goyang-si (KR); Jinseul Ahn, Goyang-si (KR)

(73) Assignee: LG Display Co., Ltd., Seoul (KR)

(21) Appl. No.: 18/886,554

(22) Filed: Sep. 16, 2024

(30) Foreign Application Priority Data
Jan. 24, 2024 (KR) 10-2024-0010837

(51) Int. Cl. H10K 59/131; H10K 77/10; H10K 102/00

(52) U.S. Cl. CPC H10K 59/1315; H10K 77/111; H10K 2102/311

(57) ABSTRACT

A flexible display device may include: a substrate including an active area and a non-active area including a bending area; a first gate link line disposed above the substrate in the non-active area including in the bending area; a second gate link line disposed below the first gate link line and connected to the first gate link line through at least one first contact hole in the non-active area outside the bending area; a plurality of signal lines disposed below the second gate link line and connected to the second gate link line respectively through a plurality of second contact holes in the non-active area outside the bending area; a trench disposed in the non-active area and enclosing the at least one first contact hole, the plurality of second contact holes, and the second gate link line in a plan view; and an inorganic insulating layer disposed in the trench.

### CROSS-REFERENCE TO RELATED APPLICATION

This application claims the priority of Korean Patent Application No. 10-2024-0010837, filed on Jan. 24, 2024, in the Korean Intellectual Property Office, the disclosure of which is incorporated herein by reference.

### BACKGROUND

### Field

The present disclosure relates to a flexible display device, and more particularly to a flexible display device which is capable of reducing a bezel width.

### Description of the Related Art

As the society enters the information era, a field of a display device for visually expressing electrical information signals has been rapidly developing, and studies have continued to improve performances of various display devices, such as a thinner profile, a lighter weight, and lower power consumption.

A representative display device may include a liquid crystal display (LCD) device, a field emission display (FED) device, an electro-wetting display (EWD) device, an organic light emitting display (OLED) device, and the like.

An electroluminescent display device which is represented, e.g., by an organic light emitting display device is a self-emitting display device not requiring a separate light source, which is different from a liquid crystal display device. Therefore, the electroluminescent display device may be manufactured to have a light weight and a small thickness. Further, since the electroluminescent display device is advantageous not only in terms of power consumption due to the low voltage driving, but also in terms of color implementation, a response speed, a viewing angle, a contrast ratio (CR), it is expected to be utilized in various fields.

In the electroluminescent display device, an emissive layer EML is disposed between two electrodes configured by an anode and a cathode. When holes in the anode are injected into the emissive layer and electrons in the cathode are injected into the emissive layer, the injected holes and electrons are recombined and form excitons in the emissive layer to emit light.

### SUMMARY

As the size of the display device is reduced, efforts are continued to reduce a bezel area (i.e., an outer periphery of the display area) to increase an effective display screen size with the same surface area of the display device.

However, in the bezel area corresponding to a non-display area, wiring lines and a

driving circuit for driving the display screen are disposed so that there is a limitation in reducing the bezel area.

Recently, with regard to a flexible electroluminescent display device which maintains a display performance even though it is bent by applying a flexible substrate of a flexible material such as plastic, there is an effort to reduce the bezel area by bending the non-display area of the flexible substrate to reduce the bezel area while ensuring a sufficient area for the wiring lines and the driving circuit.

For the electroluminescent display device using a flexible substrate, such as plastic, the flexibility of various insulating layers disposed on the substrate and the wiring lines formed of a metal material is needed to suppress such potential defects as a crack which may be caused by the bending. Further, moisture may permeate through an exposed organic film in a contact area between gate link lines between the bending area and the active area, which may result in a corrosion defect.

Therefore, inventors of the present disclosure recognized the above-mentioned problems and carried out several experiments to mitigate the corrosion defect of the wiring lines in the contact area between the gate link lines and to improve the reliability of the flexible display device. As a result of the experiments, a novel flexible display device which minimized the corrosion defects of the wiring lines in the contact area was invented.

An object to be achieved by example embodiments of the present disclosure is to provide a flexible display device which minimizes a corrosion defect of a wiring line in a contact area.

Objects of the present disclosure are not limited to the above-mentioned objects, and other objects, which are not mentioned above, can be clearly understood by those skilled in the art from the following descriptions.

To achieve these objects and other advantages of the present disclosure, as embodied and broadly described herein, a flexible display device may include: a substrate including an active area and a non-active area, the non-active area including a driving circuit, a bending area, and a contact area between the driving circuit and the bending area; a plurality of signal lines on the substrate and extending between the driving circuit and the contact area; a first gate link line disposed above the plurality of signal lines in the contact area, the first gate link line being connected to each of the plurality of signal lines respectively through a plurality of first contact holes; a first planarization layer on the first gate link line; a second gate link line on the first planarization layer and connected to the first gate link line through at least one second contact hole; a second planarization layer and a bank on the second gate link line; and a trench penetrating at least the bank, the trench enclosing the plurality of first contact holes, at least one second contact hole, and the second gate link line in a plan view.

According to another aspect of the present disclosure, a flexible display device may include: a substrate including an active area and a non-active area including a bending area; a first gate link line disposed above the substrate in the non-active area including in the bending area; a second gate link line disposed below the first gate link line and connected to the first gate link line through at least one first contact hole in the non-active area outside the bending area; a plurality of signal lines disposed below the second gate link line and connected to the second gate link line respectively through a plurality of second contact holes in the non-active area outside the bending area; a trench disposed in the non-active area and enclosing the at least one first contact hole, the plurality of second contact holes, and the second gate link line in a plan view; and an inorganic insulating layer disposed in the trench.

Other detailed matters of example embodiments are included in the detailed description and the drawings.

According to example embodiments of the present disclosure, in the flexible display device, the bezel width is reduced to improve the aesthetics.

According to example embodiments of the present disclosure, in the flexible display device, the corrosion defect of the wiring lines in the contact area is mitigated to improve the reliability of the flexible display device.

The advantages and effects according to the present disclosure are not limited to those described above, and additional advantages and effects are included in or may be obtained from the present disclosure.

Additional features and aspects of the disclosure will be set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the disclosure and are incorporated in and constitute a part of this application, illustrate example embodiments of the disclosure and together with the description serve to explain the principles of the disclosure. In the drawings:

FIG. 1 is a block diagram of a flexible display device according to an example embodiment of the present disclosure;

FIG. 2 is a circuit diagram of an example sub pixel of a flexible display device according to an example embodiment of the present disclosure;

FIG. 3 is a plan view of a flexible display device according to an example embodiment of the present disclosure;

FIG. 4 is a perspective view of a flexible display device according to an example embodiment of the present disclosure;

FIG. 5 is a perspective view of a bending state of a flexible display device according to an example embodiment of the present disclosure;

FIG. 6A is a cross-sectional view taken along the line I-I′ in FIG. 3;

FIG. 6B is a cross-sectional view taken along the line II-II′ in FIG. 3;

FIG. 7 is an enlarged view of part A of FIG. 3;

FIG. 8 is an enlarged view of part B of FIG. 7;

FIG. 9 is a cross-sectional view taken along the line A-A′ in FIG. 8;

FIG. 10 is a cross-sectional view taken along the line B-B′ in FIG. 8;

FIG. 11 is a plan view of a contact area of a flexible display device according to another example embodiment of the present disclosure; and

FIG. 12 is a cross-sectional view taken along the line C-C′ in FIG. 11.

### DETAILED DESCRIPTION

Advantages and features of the present disclosure and methods of achieving them will become apparent with reference to the example embodiments described below in detail in conjunction with the accompanying drawings. The present disclosure may, however, be embodied in different forms and should not be construed as limited to the example embodiments set forth herein. Rather, these example embodiments are provided so that this disclosure will be thorough and complete and will fully convey the scope of the present disclosure to those skilled in the art.

The shapes, sizes, ratios, angles, numbers, and the like, illustrated in the accompanying drawings for describing various example embodiments of the present disclosure, are merely given by way of example. Therefore, the present disclosure is not limited to such illustrated details in the drawings.

In the following description, where a detailed description of a relevant known function or configuration may unnecessarily obscure aspects of the present disclosure, a detailed description of such a known function or configuration may be omitted or be briefly discussed.

Where a term like “include,” “have,” or “consist of” is used, one or more other elements may be added unless the term is used with a more limiting term, such as “only” or the like. An element described in a singular form may include a plurality of elements, and vice versa, unless the context clearly indicates otherwise.

In construing an element, the element should be construed as including an error or tolerance range even where no explicit description of such an error or tolerance range is provided.

Where a positional relationship between two elements is described with such a term as “on,” “above,” “below,” “next,” or the like, one or more other elements may be located between the two elements unless the term is used with a more limiting term, such as “immediate(ly)” or “direct(ly).”

For example, where a first element is described as being positioned “on” a second element, the first element may be positioned above and contact the second element or may merely be above the second element with one or more additional elements disposed between the first and second elements.

Although terms “first,” “second,” and the like may be used herein to describe various elements, these elements should not be interpreted to be limited by these terms as they are not used to define a particular essence, order, sequence, precedence, or number of such elements. These terms are used only to refer to one element separately from another. For example, a first element could be termed a second element, and a second element could similarly be termed a first element, without departing from the scope of the present disclosure.

Like reference numerals generally denote like elements throughout the specification, unless otherwise specified.

A size and a thickness of each component illustrated in the drawing are illustrated for convenience of description, and the present disclosure is not limited to the size and the thickness of the component illustrated.

Features of various embodiments of the present disclosure may be partially or wholly coupled to or combined with each other, and may be operated, linked, or driven together in various ways as those skilled in the art can sufficiently understand. The embodiments of the present disclosure may be carried out independently from each other or may be carried out together in association with each other.

Hereinafter, a flexible display device according to example embodiments of the present disclosure will be described in detail with reference to the accompanying drawings.

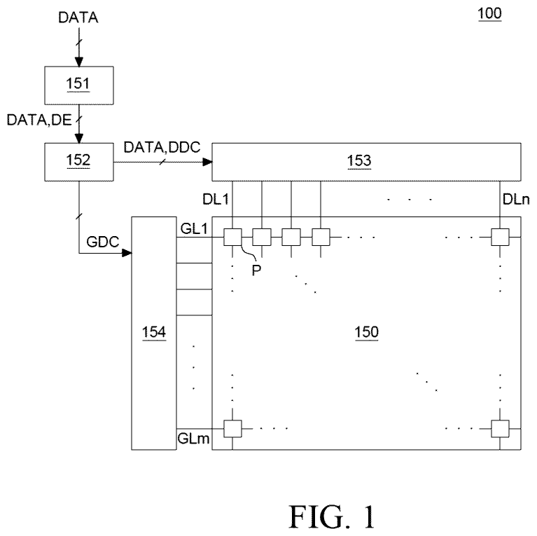

FIG. 1 is a block diagram of a flexible display device according to an example embodiment of the present disclosure.

As shown in FIG. 1, a flexible display device 100 according to an example embodiment of the present disclosure may include an image processor 151, a timing controller 152, a data driving circuit 153, a gate driving circuit 154, and a display panel 150.

First, the image processor 151 may output a data signal DATA supplied from an external source and a data enable signal DE. The image processor 151 may output one or more of a vertical synchronization signal, a horizontal synchronization signal, and a clock signal in addition to the data enable signal DE.

The timing controller 152 may be supplied with the data signal DATA together with one or more driving signals, including the data enable signal DE, the vertical synchronization signal, the horizontal synchronization signal, and/or the clock signal, from the image processor 151. The timing controller 152 may output a gate timing control signal GDC for controlling an operation timing of the gate driving circuit 154 and a data timing control signal DDC for controlling an operation timing of the data driving circuit 153, based on the driving signal(s).

Further, the data driving circuit 153 may sample and latche the data signal DATA supplied from the timing controller 152 in response to the data timing control signal DDC supplied from the timing controller 152 to convert the data signal into a gamma reference voltage and may output the converted gamma reference voltage. The data driving circuit 153 may be a data driver. The data driving circuit 153 may output the data signal DATA through data lines DL1 to DLn.

The gate driving circuit 154 may output the gate signal while shifting a level of the gate voltage, in response to the gate timing control signal GDC supplied from the timing controller 152. The gate driving circuit 154 may output the gate signal through gate lines GL1 to GLm. The gate driving circuit 154 may be a gate driver.

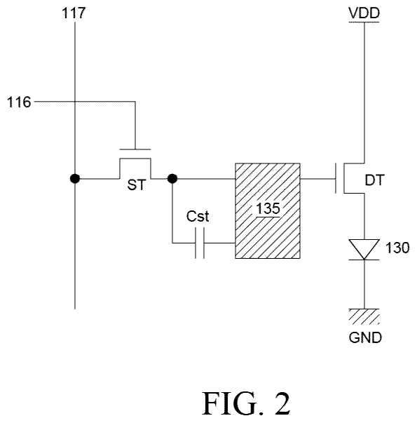

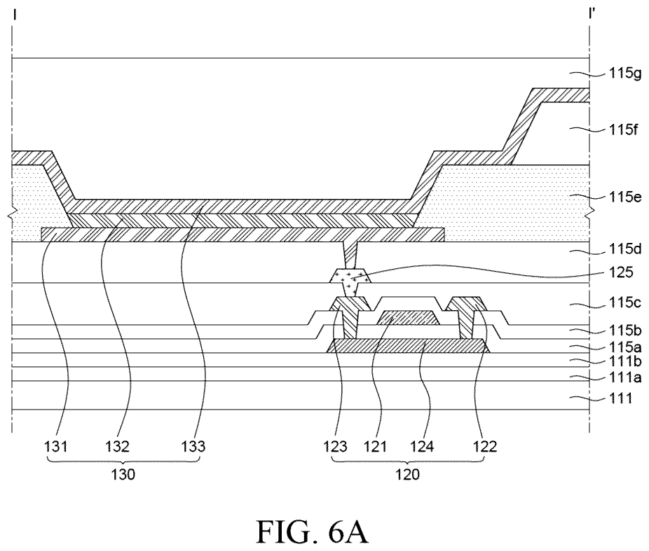

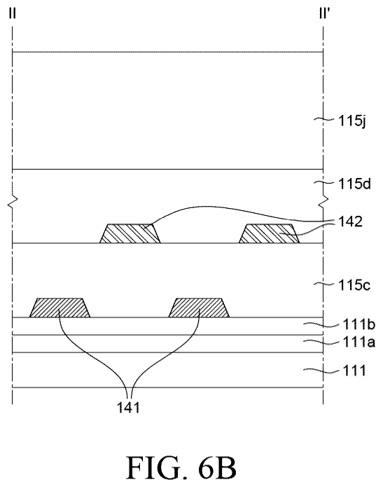

Further, the display panel 150 may display images while a sub pixel SP emits light in response to the data signal DATA and the gate signal supplied respectively from the data driving circuit 153 and the gate driving circuit 154. A detailed structure of the sub pixel SP will be described in detail with reference to FIGS. 2 and 6A.

FIG. 2 is a circuit diagram of an example sub pixel of a flexible display device according to an example embodiment of the present disclosure.

As illustrated in FIG. 2, the sub pixel of the flexible display device according to an example embodiment of the present disclosure may include a switching transistor ST, a driving transistor DT, a compensation circuit 135, and a light emitting diode 130.

The light emitting diode 130 may operate to emit light in accordance with a driving current formed by the driving transistor DT.

The switching transistor ST may perform a switching operation such that a data signal supplied through the data line 117 is stored in a capacitor Csr as a data voltage in response to a gate signal supplied through the gate line 116.

The driving transistor DT may operate to flow a constant driving current between a high potential power line VDD and a low potential power line GND in response to a data voltage stored in the capacitor CST.

The compensation circuit 135 is a circuit for compensating for a threshold voltage of the driving transistor DT and may include one or more thin film transistors and capacitors. A configuration of the compensation circuit 135 may vary depending on a compensating method.

The example sub pixel illustrated in FIG. 2 is configured by a 2T (transistor) 1C (capacitor) structure, including a switching transistor ST, a driving transistor DT, a capacitor C_{ST}, and a light emitting diode 130. When the compensation circuit 135 is added, the sub pixel may be configured in various forms, such as 3TIC, 4T2C, 5T2C, 6TIC, 6T2C, 7TIC, and 7T2C.

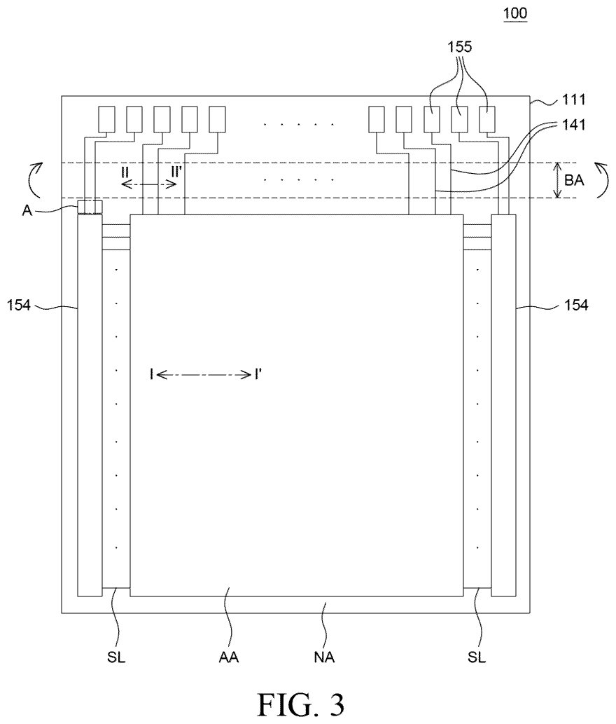

FIG. 3 is a plan view of a flexible display device according to an example embodiment of the present disclosure.

Specifically, FIG. 3 illustrates an example state in which a flexible substrate 111 of the flexible display device 100 according to the example embodiment of the present disclosure is not bent.

As illustrated in FIG. 3, the flexible display device 100 may include a display area AA, in which a pixel configured to emit light by a thin film transistor and a light emitting diode is disposed on the flexible substrate 111, and a non-display area NA which may be a bezel area enclosing an edge of the display area AA.

In the non-active area NA of the substrate 111, a circuit (e.g., a gate driving circuit 154) for driving the flexible display device 100 and various wiring lines (e.g., a scan or gate line SL) may be disposed.

The circuit for driving the flexible display device 100 may be disposed on the substrate 111 in a gate in panel (GIP) manner or connected to the substrate 111 in a tape carrier package (TCP) or a chip on film (COF) manner.

At one side of the substrate 111 in the non-active area NA, a plurality of pads 155 may be disposed so that an external module may be bonded thereto.

Here, a part of the non-active area NA of the substrate 111 may be bent in a bending direction as illustrated by an arrow to form a bending area BA.

The non-active area NA of the substrate 111 is an area where one or more wiring lines (e.g., 141) and a driving circuit for driving a screen may be disposed. The non-active area NA is not an area where the images are displayed so that the non-active area does not need to be visible from a top surface of the substrate 111. Accordingly, a partial area (e.g., BA) of the non-active area NA of the substrate 111 may be bent to reduce the bezel area while ensuring a sufficient area for the wiring lines (e.g., 141) and the driving circuit.

Various wiring lines may be formed on the substrate 111. The wiring lines may be formed in the active area AA of the substrate 111 and the wiring lines 141 formed in the non-active area NA may connects the driving circuit, the gate driving circuit 154, and the data driving circuit to each other to transmit a signal.

The wiring line(s) 141 may be formed of a conductive material and may be formed of a conductive material having an excellent ductility to reduce the risk of a crack being generated at the time of bending the substrate 111. For example, the wiring line(s) 141 may be formed of a conductive material having an excellent ductility, such as gold (Au), silver (Ag), or aluminum (Al), or may be formed of one of various conductive materials used in the display area AA. The wiring line(s) 141 may also be formed of molybdenum (Mo), chrome (Cr), titanium (Ti), nickel (Ni), neodymium (Nd), copper (Cu), or an alloy of silver (Ag) and magnesium (Mg).

The wiring line(s) 141 may be configured by a multi-layered structure including various conductive materials and for example, configured by a triple-layered structure of titanium (Ti)/aluminum (Al)/titanium (Ti), but is not limited thereto.

When the wiring line(s) 141 formed in the bending area BA are bent, a tensile force is applied thereto. For example, the largest tensile force may be applied to the wiring line(s) 141 which extend in the same direction as the bending direction so that those wiring line(s) may be more susceptible to being cracked or disconnected. Therefore, the wiring line(s) 141 may be formed not to extend in the bending direction, but at least a part of the wiring line(s) 141 disposed to include the bending area BA may be formed to extend in a different direction from the bending direction, that is, in a diagonal direction, so that the tensile force may be reduced or minimized.

The wiring line(s) 141 disposed in the bending area BA may be formed in various shapes, for example, may be formed with a trapezoidal wave shape, a triangular wave shape, a sawtooth wave shape, a sinusoidal wave shape, an omega (Ω) shape, or a rhombus shape.

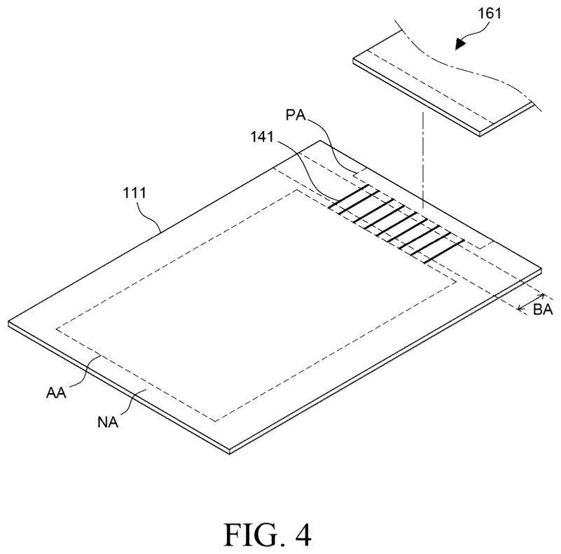

FIG. 4 is a perspective view of a flexible display device according to an example embodiment of the present disclosure,

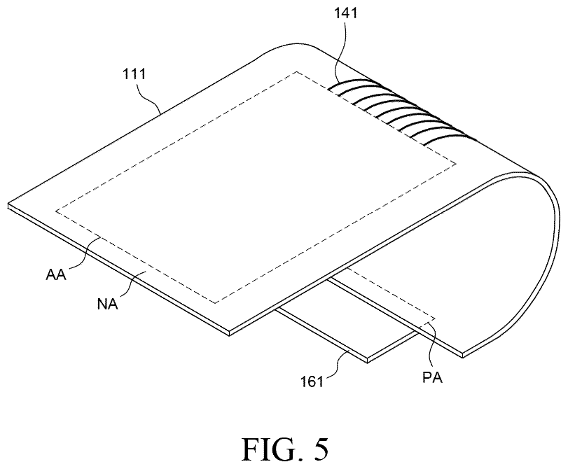

FIG. 5 is a perspective view of a bending state of a flexible display device according to an example embodiment of the present disclosure.

FIGS. 4 and 5 illustrate an example in which one side, for example, a lower side of the flexible display device is bent.

As shown in FIG. 4, the flexible display device according to an example embodiment of the present disclosure may include a substrate 111 and a circuit element 161.

The substrate 111 may be partitioned into an active area AA and a non-active area NA which is a bezel area enclosing or adjacent to an edge of the active area AA.

The non-active area AA may further include a pad area PA located toward an edge of the substrate 111 from the bending area BA.

A plurality of sub pixels may be disposed in the active area AA. The sub pixels disposed in the display area AA may include the red (R), green (G), and blue (B) sub pixels or the R, G, B, and W (white) sub pixels to implement full colors. The sub pixels may be partitioned by gate lines and data lines which intersect each other.

The circuit element 161 may include bumps (or terminals). The bumps of the circuit element 161 may be bonded to pads of the pad area PA by means of an anisotropic conductive film.

The circuit element 161 may be a chip on film (COF) in which a driving IC is mounted in a flexible film. Further, the circuit element 161 may be implemented by a COG type to be directly bonded to the pads on the substrate 111 by a chip on glass (COG) process. Further, the circuit element 161 may be a flexible circuit, such as a flexible flat cable (FFC) or a flexible printed circuit (FPC). In the following example embodiment, as an example of the circuit element 161, the COF will be mainly described, but the present disclosure is not limited thereto.

Driving signals supplied through the circuit element 161, such as a gate signal and a data signal, may be supplied to the gate line and the data lines of the active area AA through the wiring line(s) 141, such as a routing line.

In the flexible display device, a sufficient space where the pad area PA and the circuit element 161 can be located needs to be ensured in addition to the active area AA in which an input image may be rendered. The space may correspond to a bezel area, and the bezel area may be perceived by the user located on the front surface of the flexible display device, which may negatively impact the aesthetics of the display device.

As illustrated in FIG. 5, in the case of the flexible display device according to an example embodiment of the present disclosure, a lower edge of the substrate 111 may be bent in a rear direction to have a predetermined curvature.

The lower edge of the substrate 111 may correspond to an area outside of the active area AA and may correspond to an area where the pad area PA is located. As the substrate 111 is bent, the pad area PA may be located to overlap the active area AA at the rear of the active area AA. Accordingly, the bezel area which is perceived from the front surface of the flexible display device may be minimized. Therefore, the bezel width may be reduced so that the aesthetics may be improved.

To this end, the substrate 111 may be formed of a flexible material which is bendable. For example, the substrate 111 may be formed of a plastic material, such as polyimide (PI). For example, the wiring line(s) 141 may be formed of a material having flexibility. For example, the wiring line(s) 141 may be formed of a material, such as metal nano wire, metal mesh, or carbon nano tube (CNT), but it is not limited thereto.

In the meantime, the wiring line(s) 141 according to the example embodiment of the present disclosure may be disposed with a multi-layered structure (or a double wiring structure) in the non-active area NA including the bending area BA. Therefore, there is a margin for a layout of wiring lines, which makes it easier to design the layout of the wiring lines and/or electrodes.

FIG. 6A is a cross-sectional view taken along the line I-I′ in FIG. 3.

FIG. 6B is a cross-sectional view taken along the line II-II′ in FIG. 3.

FIG. 6A illustrates a cross-sectional structure of the active area AA described in FIG. 3 in detail, and FIG. 6B illustrates a cross-sectional structure of the bending area BA described in FIG. 3 in detail.

As shown in FIG. 6A, the substrate 111 may serve to support and protect components of the flexible display device disposed above the substrate 111.

The flexible substrate 111 may use a ductile material having a flexible characteristic, such as plastic.

The substrate 111 may be a film type including one from a group consisting of a polyester-based polymer, a silicon-based polymer, an acrylic-based polymer, a polyolefin-based polymer, and a copolymer thereof.

The substrate 111 may include a first substrate, a second substrate, and an insulating film. The insulating film may be disposed between the first substrate and the second substrate. As described above, the substrate 111 may be configured by the first substrate, the second substrate, and the insulating film to suppress the moisture permeation. For example, the first substrate and the second substrate may be polyimide (PI) substrates.

Buffer layers 111a and 111b may be further disposed on the substrate 111. The buffer layers 111a and 111b may suppress the permeation of moisture or other external impurities through the substrate 111 and may planarize the surface of the substrate 111.

Here, the buffer layers 111a and 111b are not essential components and may be omitted depending on a type of a thin film transistor 120 disposed on the substrate 111.

The thin film transistor 120 may be disposed above the substrate 111.

For example, the thin film transistor 120 may include a gate electrode 121, a source electrode 122, a drain electrode 123, and a semiconductor layer 124.

In this case, the semiconductor layer 124 may be configured by amorphous silicon or polycrystalline silicon, but is not limited thereto. The polycrystalline silicon has better mobility than the amorphous silicon does and therefore may have lower power consumption and better reliability. Therefore, the polycrystalline silicon may be applied to the driving thin film transistor in the pixel.

Further, the semiconductor layer 124 may be configured by an oxide semiconductor. The oxide semiconductor has excellent mobility and uniformity. For example, the semiconductor layer may be configured by oxide semiconductor, such as (1) an indium tin gallium zinc oxide (InSnGaZnO) based material which is a quaternary metal oxide, (2) an indium gallium zinc oxide (InGaZnO) based material, an indium tin zinc oxide (InSnZnO) based material, a tin gallium zinc oxide (SnGaZnO) based material, an aluminum gallium zinc oxide (AlGaZnO) based material, an indium aluminum zinc oxide (InAlZnO) based material, and a tin aluminum zinc oxide (SnAlZnO) based material which are ternary metal oxides, (3) an indium zinc oxide (InZnO) based material, an aluminum zinc oxide (AlZnO) based material, a tin zinc oxide (SnZnO) based material, a zinc magnesium oxide (ZnMgO) based material, a tin magnesium oxide (SnMgO) based material, an indium gallium oxide (InGaO) based material which are bimetallic oxides, (4) an indium oxide (InO) based material, (5) a tin oxide (SnO) based material, (6) a zinc oxide (ZnO), and (7) an indium magnesium oxide (InMgO) based material, but a composition ratio of individual elements is not limited.

The oxide thin film transistor 120 in which the semiconductor layer 124 is configured by the oxide semiconductor may perform GIP driving at 1 to 10 Hz based on an excellent off-current characteristic as compared with the low temperature polycrystalline silicon (LTPS) thin film transistor of the related art, so that low power driving may be implemented.

The semiconductor layer 124 may include a source region and a drain region including a p-type or n-type impurity, as well as a channel region between the source region and the drain region. The semiconductor layer 124 may further include a lightly doped region between the source region and the drain region adjacent to the channel region.

The source region and the drain region are areas where the impurities are highly doped, and the source electrode 122 and the drain electrode 123 of the thin film transistor 120 may be connected thereto, respectively.

As an impurity ion, a p-type impurity or an n-type impurity may be used. The p-type impurity may be one of boron (B), aluminum (Al), gallium (Ga), and indium (In), and the n-type impurity may be one of phosphorus (P), arsenic (As), and antimony (Sb).

Further, the channel region of the semiconductor layer 124 may be doped with the n-type impurity or the p-type impurity in accordance with the NMOS or PMOS thin film transistor structure. As the thin film transistor included in the flexible display device according to an example embodiment of the present disclosure, the NMOS or the PMOS thin film transistor may be applicable.

A first insulating layer 115a may be disposed on the semiconductor layer 124.

The first insulating layer 115a may be configured by a single layer or a plurality of layers of silicon oxide (SiOx) or silicon nitride (SiNx) and may be disposed such that the current flowing in the semiconductor layer 124 does not flow into the gate electrode 121. The silicon oxide has a poorer ductility than a metal but has a better ductility than the silicon nitride so that it may be configured by a single layer or a plurality of layers depending on the intended characteristic or application.

The gate electrode 121 may be disposed on the first insulating layer 115a.

The gate electrode 121 may serve as a switch which turns the thin film transistor 120 on or off based on an electric signal transmitted, e.g., from another circuit element like a switching transistor ST (see FIG. 2) connected to a data line and a gate line, to the gate electrode 121. The gate electrode may be configured by a single layer or a plurality of layers of copper (Cu), aluminum (Al), molybdenum (Mo), chrome (Cr), gold (Au), titanium (Ti), nickel (Ni), and neodymium (Nd) which are conductive metals, or an alloy thereof, but is not limited thereto.

A second insulating layer 115b may be disposed on the gate electrode 121.

Here, the second insulating layer 115b may be configured by a single layer or a plurality of layers of silicon oxide (SiOx) or silicon nitride (SiNx) to insulate the gate electrode 121 from the source electrode 122 and the drain electrode 123.

The source electrode 122 and the drain electrode 123 may be disposed on the second insulating layer 115b.

The source electrode 122 or the drain electrode 123 may receive a high potential voltage (e.g., VDD in FIG. 2) to transmit a driving current from the thin film transistor 120 to the light emitting diode 130.

For example, the source electrode 122 and the drain electrode 123 may be configured by a single layer or a plurality of layers of copper (Cu), aluminum (Al), molybdenum (Mo), chrome (Cr), gold (Au), titanium (Ti), nickel (Ni), and neodymium (Nd) which are conductive metals, or an alloy thereof, but it is not limited thereto.

A protection layer (not shown) which is configured by an inorganic insulating layer, such as silicon oxide (SiOx) or silicon nitride (SiNx), may be further disposed on the thin film transistor 120 configured as described above.

The protection layer may serve to suppress unnecessary electrical connection between components above and below the protection layer and to suppress contamination or damage from the outside. However, the protection layer may be omitted in accordance with a configuration and a characteristic of the thin film transistor 120 and the light emitting diode 130.

The thin film transistor 120 may be classified into an inverted staggered structure and a coplanar structure depending on the position of the components which configure the thin film transistor 120. For example, in the thin film transistor with an inverted staggered structure, the gate electrode may be located on the opposite side of the semiconductor layer from the source electrode and the drain electrode. In contrast, as illustrated in FIG. 6A, in the thin film transistor 120 with a coplanar structure, the gate electrode 121 may be located on the same side of the semiconductor layer 124 as the source electrode 122 and the drain electrode 123.

Even though the thin film transistor 120 with a coplanar structure is illustrated in FIG. 6A, the flexible display device according to an example embodiment of the present disclosure may include a thin film transistor with an inverted staggered structure.

For the convenience of description, among various thin film transistors which may be implemented in the flexible display device, only the driving thin film transistor 120 is illustrated, but such additional elements as a switching thin film transistor and a capacitor may also be included in the flexible display device.

When a signal is applied from the gate line (e.g., 116 in FIG. 2), the switching thin film transistor (e.g., ST in FIG. 2) may transmit a signal from the data line (e.g., 117 in FIG. 2) to the gate electrode 121 of the driving thin film transistor 120. The driving thin film transistor 120 may transmit a current, which is transmitted through a power line based on the signal transmitted from the switching thin film transistor ST, to the anode 131 and may control the emission of light based on the current transmitted to the anode 131.

Planarization layers 115c and 115d may be disposed above the thin film transistor 120. The planarization layers 115c and 115d may be disposed to protect the thin film transistor 120, relieve a step generated due to the thin film transistor 120, and reduce a parasitic capacitance generated between the thin film transistor 120 and the gate line and the data line, and the light emitting diodes 130.

For example, the planarization layers 115c and 115d may be formed of one or more materials of acrylic resin, epoxy resin, phenolic resin, polyamides resin, polyimides resin, unsaturated polyesters resin, polyphenylene resin, polyphenylene sulfides resin, and benzocyclobutene, but are not limited thereto.

As illustrated in FIG. 6A, the planarization layers 115c and 115d may have a multi-layered structure configured by at least two layers and may include a first planarization layer 115c and a second planarization layer 115d. The first planarization film 115c may be disposed so as to cover the thin film transistor 120 and may expose a part of the source electrode 122 and the drain electrode 123 of the thin film transistor 120.

The planarization layers 115c and 115d may be an overcoat layer but are not limited thereto.

Here, an intermediate electrode 125 may be disposed on the first planarization film 115c to electrically connect the thin film transistor 120 with the light emitting diode 130. Further, even though not illustrated in FIG. 6A, various metal layers serving as wiring lines/electrodes, such as a data line or a signal line, may be disposed on the first planarization film 115c.

Further, the second planarization layer 115d may be disposed on the first planarization layer 115c and the intermediate electrode 125.

In the flexible display device according to the first example embodiment of the present disclosure, the planarization layers 115c and 115d may be formed as two layers because, as the resolution of the display panel becomes higher, the number of signal lines is increased. Therefore, it is difficult to dispose all the wiring lines on one layer (e.g., 115c) while ensuring a minimum interval between them. Thus, an additional layer may be provided. The additional layer, that is, the second planarization layer 115d, may be added so that there is a greater margin for a layout of wiring lines, which makes designing the layout of the wiring lines/electrodes easier. Further, where a dielectric material is used for the planarization layers 115c and 115d configured as a plurality of layers, the planarization layers 115c and 115d may be utilized to form a capacitance between metal layers.

The second planarization layer 115d may be formed to expose a part of the intermediate electrode 125, and the drain electrode 123 of the thin film transistor 120 and the anode 131 of the light emitting diode 130 may be electrically connected via the intermediate electrode 125.

The light emitting diode 130 may be disposed above the second planarization layer 115d.

The light emitting diode 130 may include an anode 131, a light emitting layer 132, and a cathode 133.

The anode 131 may be disposed on the second planarization layer 115d.

The anode 131 may be an electrode serving to supply holes to the light emitting unit (or layer) 132 and may be connected to the intermediate electrode 125 through the contact hole formed in the second planarization layer 115d to be electrically connected to the thin film transistor 120.

The anode 131 may be configured by indium tin oxide (ITO) and/or indium zin oxide (IZO), which are transparent conductive materials, but is not limited thereto.

Where the flexible display device is a top emission type which emits light to an upper portion on which the cathode 133 is disposed, the flexible display device 100 may further include a reflective layer to cause the emitted light to be reflected from the anode 131 and be more easily emitted to an upper direction where the cathode 133 is disposed. For example, the anode 131 may have a double-layered structure in which a transparent conductive layer configured by a transparent conductive material and a reflective layer are sequentially laminated or may have a triple-layered structure in which a transparent conductive layer, a reflective layer, and a transparent conductive layer are sequentially laminated. The reflective layer may be silver (Ag) or an alloy including silver.

A bank 115e may be disposed above the anode 131 and the second planarization layer 115d.

The bank 115e may partition an area in which light is emitted to define a sub pixel. For example, the bank 115e may be formed by the photolithographic process after forming a photoresist on the anode 131.

The photoresist refers to a photosensitive resin whose solubility in a developer is changed by the action of light, and a specific pattern may be obtained by exposing and developing the photoresist. The photoresist may be classified into a positive photoresist and a negative photoresist. The positive photoresist is a photoresist whose solubility of the exposed portion in the developer is increased by the exposure. When the positive photoresist is developed, a pattern from which exposed portions are removed may be obtained. The negative photoresist is a photoresist whose solubility of the exposed portion in the developer is significantly lowered by the exposure. When the negative photoresist is developed, a pattern from which non-exposed portions are removed may be obtained.

In order to form the light emitting unit (or layer) 132 of the light emitting diode 130, a fine metal mask (FMM), which is a deposition mask, may be used.

Here, to suppress a potential damage caused by contact with the deposition mask disposed on the bank 115e and to maintain a predetermined distance between the bank 115e and the deposition mask, a spacer 115f may be disposed above the bank 115e. The spacer 115f may be configured by one of polyimide, photoacryl, and benzocyclobutene (BCB).

The light emitting unit (or layer) 132 may be disposed between the anode 131 and the cathode 133.

The light emitting unit (or layer) 132 may serve to emit light and may include at least one of a hole injection layer (HIL), a hole transport layer (HTL), an emissive layer, an electron transport layer (ETL), and an electron injection layer (EIL). Some component layers may be omitted depending on the structure or the characteristic of the flexible display device. Here, as the emissive layer, an electroluminescent emissive layer and/or an inorganic emissive layer may be applied.

The hole injection layer may be disposed on the anode 131 to smoothly inject the holes.

The hole transport layer may be disposed on the hole injection layer to smoothly transmit the holes to the emissive layer.

The emissive layer may be disposed on the hole transport layer and may include a material which emits light of a specific color. Further, the light emitting material may be formed using a phosphor material or a fluorescent material.

The electron injection layer may be further disposed on the electron transport layer. The electron injection layer is an organic layer which may smoothly inject the electrons from the cathode 133 and may be omitted in accordance with the intended structure and characteristic of the flexible display device.

In the meantime, an electron blocking layer or a hole blocking layer, which blocks the flow of holes or electrons, may further be disposed to be close to the emissive layer. Therefore, a phenomenon of the electrons moving from the emissive layer to pass through an adjacent hole transport layer when the electrons are injected to the emissive layer or of the holes moving from the emissive layer to pass through an adjacent electron transport layer when the holes are injected to the emissive layer may be suppressed. Therefore, the luminous efficiency may be improved.

The cathode 133 may be disposed on the light emitting unit 132 to supply electrons to the light emitting unit 132. Since the cathode 133 is to supply electrons here, the cathode 133 may be configured by a conductive metal material having a low work function, such as magnesium (Mg) or silver-magnesium, but is not limited thereto.

Where the flexible display device is a top emission type, the cathode 133 may be formed with indium tin oxide (ITO), indium zinc oxide (IZO), indium tin zinc oxide (ITZO), zinc oxide (ZnO), and/or tin oxide (TO) based transparent conductive oxide.

Further, an encapsulating unit (or layer) 115g may be disposed above the light emitting diode 130 to suppress oxidation or damage of the thin film transistor 120 and the light emitting diode 130, which are components of the flexible display device 100, due to moisture, oxygen, or impurities entering from the outside. The encapsulating unit 115g may be formed by laminating a plurality of encapsulating layers and a particle compensating layer, and a plurality of barrier films.

The encapsulating unit (or layer) 115g may be disposed on an entire upper surface of the thin film transistor 120 and the light emitting diode 130 and may be configured by one of silicon nitride (SiNx) and aluminum oxide (AlyOz), which are inorganic materials, but is not limited thereto. An encapsulating layer may be further disposed on the particle compensating layer disposed on another encapsulating layer.

The particle compensating layer may be disposed on the encapsulating layer and may include silicon oxycarbon (SIOCz), acryl, or epoxy-based resin, which is an organic material, but is not limited thereto. When a defect is caused by the crack generated by foreign material or particles during the process, the particle compensating layer may compensate for the defect by covering the curvature or the foreign materials.

A barrier film may be disposed on the encapsulating layer and the particle compensating layer so that the flexible display device may delay the permeation of the oxygen and moisture from the outside. The barrier film may be formed as a light-transmissive and double-sided adhesive film and be configured by any one of olefin, acrylic, and silicon based insulating materials. Further, a barrier film configured by any one of cycloolefin polymer (COP), cycloolefin copolymer (COC), and polycarbonate (PC) may be further laminated, but the present disclosure is not limited thereto.

Even though not illustrated, a polarization film may be disposed above the encapsulating unit 115g.

A touch panel may be disposed above the polarization film. However, the present disclosure is not limited thereto. The polarization film may be disposed above the touch panel and the encapsulating unit 115g, and the polarization film may be disposed above the touch panel.

A user may directly input information onto the touch panel screen by pressing a display screen using a hand or a pen. For example, the touch panel may be considered a desirable input method under a graphical user interface (GUI) environment because a user may directly perform a desired operation while looking at the screen and any one may easily operate it. Currently, the touch panel is widely used in various fields, such as mobile phones, PDAs, banks, government offices, various medical equipment, or guidance of tourism and major institutions.

FIG. 6B is a cross-section of a detailed structure of the bending area BA described with reference to FIG. 3.

Some components of FIG. 6B are substantially same as or similar to components illustrated in FIG. 6A, and a redundant description thereof may be omitted.

The gate signal and the data signal described with reference to FIGS. 1 to 5 may be transmitted to a pixel disposed in the display area AA via circuit lines disposed in the non-display area NA of the flexible display device 100 to emit light.

If the wiring lines disposed in the non-active area NA including the bending area BA of the flexible display device 100 are formed of a single-layered structure, more spaces for disposing the wiring lines may be required. After depositing the conductive material, a conductive material may be patterned by an etching process to form a desired shape of the wiring line. However, since there is a limitation in fineness of the etching process, more spaces may be required due to the limitation in narrowing an interval between the wiring lines. Therefore, a size of the non-active area NA may be increased so that there may be a difficulty in implementing a narrow bezel.

Further, where one wiring line is used to transmit one signal, if the corresponding wiring line is cracked, the signal may not be transmitted.

A crack may be generated in a wiring line during the process of bending the substrate 111, or a crack generated in another layer may be propagated to the wiring line. As described above, if the crack is generated in the wiring line, the signal to be transmitted may not be transmitted.

Therefore, the wiring lines disposed in the bending area BA of the flexible display device 100 according to an example embodiment of the present disclosure may be disposed as double wiring lines of a first wiring line 141 and a second wiring line 142. However, the present disclosure is not limited thereto, and the wiring lines may be disposed as double wiring lines on the same layer, rather than the double wiring lines on different layers.

The first wiring line 141 and the second wiring line 142 may be formed of a conductive material. The first wiring line 141 and the second wiring line 142 may be formed of a conductive material having an excellent ductility to reduce the risk of a crack being generated during the bending of the flexible substrate 111.

The first wiring line 141 and the second wiring line 142 may be formed of a conductive material having an excellent ductility, such as gold (Au), silver (Ag), or aluminum (Al). The first wiring line 141 and the second wiring line 142 may be formed by one of various conductive materials used in the display area AA, and may also be formed of one or more of molybdenum (Mo), chrome (Cr), titanium (Ti), nickel (Ni), neodymium (Nd), copper (Cu), and an alloy of silver (Ag) and magnesium (Mg). Further, the first wiring line 141 and the second wiring line 142 may be configured by a multi-layered structure including various conductive materials and, for example, be configured by a triple-layered structure of titanium (Ti)/aluminum (Al)/titanium (Ti), but are not limited thereto.

To protect the first wiring line 141 and the second wiring line 142, a buffer layer formed of an inorganic insulating layer may be disposed below the first wiring line 141 and the second wiring line 142. Alternatively, a passivation layer formed of an inorganic insulating layer may be formed to enclose upper portions and side portions of the first wiring line 141 and the second wiring line 142. Therefore, potential corrosion of the first wiring line 141 and the second wiring line 142 caused by reaction with moisture may be avoided or reduced.

When the first wiring line 141 and the second wiring line 142 formed in the bending area BA are bent, a tensile force may be applied. As described with reference to FIG. 3, the largest tensile force may be applied to a wiring line extending in the same direction as the bending direction of the substrate 111, and a crack may be generated in the wiring line. When a severe crack is generated, the wiring line may be broken. Therefore, the wiring line may be formed not to extend in the bending direction. Rather, at least a part of the wiring line disposed in the bending area BA may be formed to extend in a diagonal direction different from the bending direction so that the applied tensile force is minimized or reduced to minimize or reduce the risk of a crack being generated. The shape of the wiring lines may be configured, e.g., by a rhombus shape, a triangular wave shape, a sinusoidal wave shape, or a trapezoidal shape, but is not limited thereto.

The first wiring line 141 may be disposed on the substrate 111, and the first planarization layer 115c may be disposed above the first wiring line 141. The second wiring line 142 may be disposed on the first planarization layer 115c, and the second planarization layer 115d may be disposed on the second wiring line 142. Here, the first planarization layer 115c and the second planarization layer 115d may be formed of one or more of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

Further, a micro coating layer (MCL) 115j may be disposed on the second planarization layer 115d.

Since a tensile force is applied to a wiring line unit disposed above the substrate 111 at the time of bending to cause a potential crack, the micro coating layer 115j may be formed by coating an area to be bent with a resin with a small thickness to protect the wiring line.

In addition, moisture may permeate through an exposed organic film in a contact area between gate link lines in the non-active area NA between the bending area and the active area and potentially result in the corrosion defect on the wiring line.

Therefore, according to an example embodiment of the present disclosure, an organic film vulnerable to moisture may be covered by an inorganic film of the touch panel by enclosing the contact area with the trench structure, which will be described in detail with reference to the drawings.

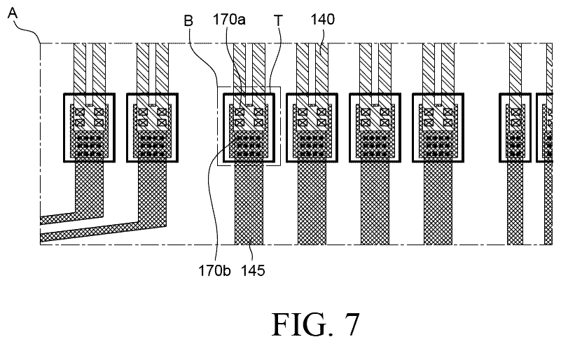

FIG. 7 is an enlarged view of part A of FIG. 3.

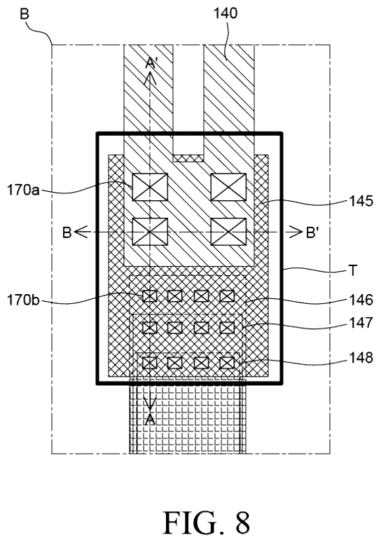

FIG. 8 is an enlarged view of part B of FIG. 7.

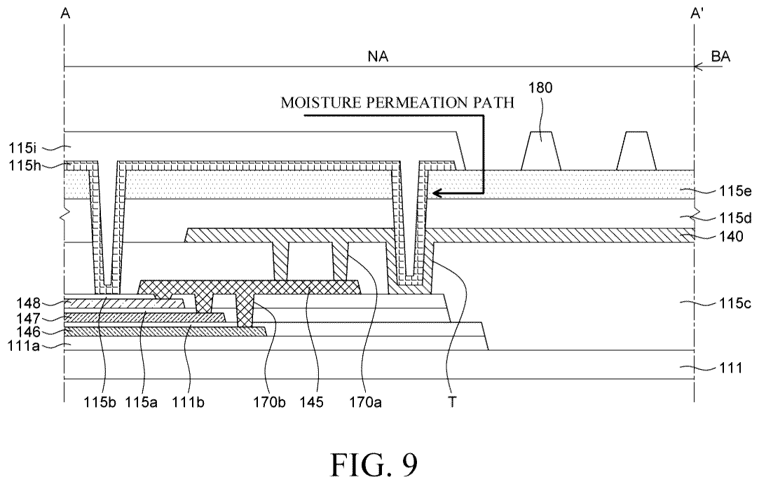

FIG. 9 is a cross-sectional view taken along the line A-A′ in FIG. 8.

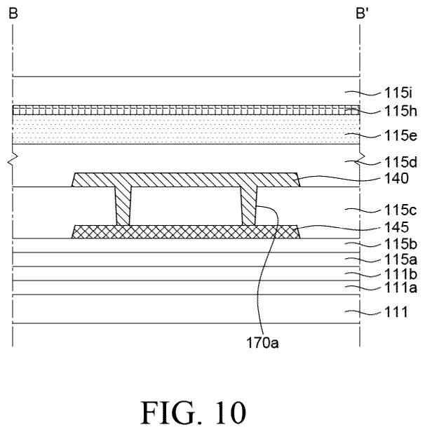

FIG. 10 is a cross-sectional view taken along the line B-B′ in FIG. 8.

FIGS. 7 to 10 illustrate a contact area between gate link lines 140 and 145 in a non-active area NA between a bending area BA and an active area AA of FIG. 3.

As shown in FIGS. 7 to 10, buffer layers 111a and 111b may be disposed on the substrate 111.

The buffer layers 111a and 111b may extend to a part of the non-active area NA, without being disposed in the bending area BA.

The substrate 111 may be a film type including one or more materials from a group consisting of a polyester-based polymer, a silicon-based polymer, an acrylic-based polymer, a polyolefin-based polymer, and a copolymer thereof.

The substrate 111 may include a first substrate, a second substrate, and an insulating film. The insulating film may be disposed between the first substrate and the second substrate. As described above, the substrate 111 may be configured by the first substrate, the second substrate, and the insulating film to suppress the moisture permeation. For example, the first substrate and the second substrate may be polyimide (PI) substrates.

A first buffer layer 111a may be disposed on the substrate 111.

The first buffer layer 111a may be configured as a single layer of silicon oxide (SiOx) or silicon nitride (SiNx), or a multi-layer thereof.

The first buffer layer 111a may extend to a part of the non-active area NA, without being disposed in the bending area BA.

A first signal line 146 may be disposed on the first buffer layer 111a.

For example, the first signal line 146 may be a gate routing line for transmitting a gate signal but is not limited thereto.

For example, the first signal line 146 may be configured by a single layer or a plurality of layers of copper (Cu), aluminum (Al), molybdenum (Mo), chrome (Cr), gold (Au), titanium (Ti), nickel (Ni), and neodymium (Nd), which are conductive metals, or an alloy thereof, but is not limited thereto.

A second buffer layer 111b may be disposed on the first signal line 146.

The second buffer layer 111b may be configured as a single layer of silicon oxide (SiOx) or silicon nitride (SiNx), or a multi-layer thereof.

The second buffer layer 111b may extend to a part of the non-active area NA, without being disposed in the bending area BA.

A second signal line 147 may be disposed on the second buffer layer 111b.

For example, the second signal line 147 may be a gate routing line for transmitting a gate signal but is not limited thereto.

For example, the second signal line 147 may be configured by a single layer or a plurality of layers of copper (Cu), aluminum (Al), molybdenum (Mo), chrome (Cr), gold (Au), titanium (Ti), nickel (Ni), and neodymium (Nd), which are conductive metals, or an alloy thereof, but is not limited thereto.

The second signal line 147 may be disposed along the first signal line 146 above the first signal line 146 but is not limited thereto.

The first insulating layer 115a may be disposed on the second signal line 147.

The first insulating layer 115a may be configured by a single layer of silicon oxide (SiOx) or silicon nitride (SiNx), or a multi-layer thereof.

The first insulating layer 115a may extend to a part of the non-active area NA, without being disposed in the bending area BA.

A third signal line 148 may be disposed on the first insulating layer 115a.

The third signal line 148 may be disposed on the same layer as the gate electrode of the active area but is not limited thereto.

For example, the third signal line 148 may be a gate routing line for transmitting a gate signal but is not limited thereto.

For example, the third signal line 148 may be configured by a single layer or a plurality of layers of copper (Cu), aluminum (Al), molybdenum (Mo), chrome (Cr), gold (Au), titanium (Ti), nickel (Ni), and neodymium (Nd), which are conductive metals, or an alloy thereof, but is not limited thereto.

The third signal line 148 may be disposed along the first signal line 146 and the second signal line 147 above the first signal line 146 and the second signal line 147, but the present disclosure is not limited thereto.

As described above, according to the present disclosure, the gate routing line may be formed as a triple layer of the first signal line 146, the second signal line 147, and the third signal line 148 so that the resistance may be significantly reduced in the same area. Further, even in the event that some of signal lines are disconnected, the gate signal may be safely transmitted to the gate driving circuit configured in the GIP manner.

The second insulating layer 115b may be disposed on the third signal line 148.

The second insulating layer 115b may be configured by a single layer of silicon oxide (SiOx) or silicon nitride (SiNx), or a multi-layer thereof.

The second insulating layer 115b may extend to a part of the non-active area NA, without being disposed in the bending area BA.

A partial area of the second buffer layer 111b, the first insulating layer 115a, and the second insulating layer 115b may be removed to form a plurality of second contact holes 170b respectively exposing a part of the first signal line 146, a part of the second signal line 147, and a part of the third signal line 148. For example, a partial area of the second insulating layer 115b may be removed to form a second contact hole 170b exposing a part of the third signal line 148. Further, a partial area of the first insulating layer 115a and the second insulating layer 115b may be removed to form another second contact hole 170b which exposes a part of the second signal line 147. Further, a partial area of the second buffer layer 111b, the first insulating layer 115a, and the second insulating layer 115b may be removed to form still another second contact hole 170b which exposes a part of the first signal line 146.

A second gate link line 145 may be disposed on the second insulating layer 115b.

The second gate link line 145 may be disposed on the same layer as the source electrode and the drain electrode of the active area, but is not limited thereto.

For example, the second gate link line 145 may be configured by a single layer or a plurality of layers of copper (Cu), aluminum (Al), molybdenum (Mo), chrome (Cr), gold (Au), titanium (Ti), nickel (Ni), and neodymium (Nd), which are conductive metals, or an alloy thereof, but is not limited thereto.

The second gate link line 145 may be connected to the first signal line 146, the second signal line 147, and the third signal line 148, respectively through the plurality of second contact holes 170b.

The second gate link line 145 may overlap respective ends of the first signal line 146, the second signal line 147, and the third signal line 148.

The first planarization layer 115c may be disposed on the second gate link line 145 so as to cover the second buffer layer 111b, the first insulating layer 115a, the second insulating layer 115b, and the second gate link line 145.

For example, the first planarization layer 115c may be formed of one or more of acrylic resin, epoxy resin, phenolic resin, polyamides resin, polyimides resin, unsaturated polyesters resin, polyphenylene resin, polyphenylenesulfides resin, and benzocyclobutene, but is not limited thereto.

The first planarization layer 115c may extend to the non-active area NA including the bending area BA. For example, in a part of the non-active area NA including the bending area BA, the first planarization layer 115c may be disposed on the substrate 111.

A partial area of the first planarization layer 115c may be removed to form a plurality of first contact holes 170a which expose parts of the second gate link line 145.

The first gate link line 140 may be disposed on the first planarization layer 115c.

The first gate link line 140 may be disposed on the same layer as the connection electrode of the active area but is not limited thereto.

For example, the first gate link line 140 may be configured by a single layer or a plurality of layers of copper (Cu), aluminum (Al), molybdenum (Mo), chrome (Cr), gold (Au), titanium (Ti), nickel (Ni), and neodymium (Nd), which are conductive metals, or an alloy thereof, but is not limited thereto.

For example, the first gate link line 140 may be connected to the second gate link line 145 through the plurality of first contact holes 170a.

For example, the first gate link line 140 may overlap one end of the second gate link line 145 and extend to the bending area BA.

For example, the first gate link line 140 may be configured as double wiring lines but is not limited thereto.

The second planarization layer 115d may be disposed on the first gate link line 140 so as to cover the first gate link line 140.

For example, the second planarization layer 115d may be formed of one or more of acrylic resin, epoxy resin, phenolic resin, polyamides resin, polyimides resin, unsaturated polyesters resin, polyphenylene resin, polyphenylene sulfides resin, and benzocyclobutene, but is not limited thereto.

The second planarization layer 115d may extend to the non-active area NA including the bending area BA.

The bank 115e may be disposed on the second planarization layer 115d.

The bank 115e may extend to the non-active area NA including the bending area BA.

A plurality of dams 180 may be disposed on the bank 115e in the non-active area NA in the vicinity of the bending area BA. For example, the dams 180 may serve to suppress the overflowing of the particle compensation layer of the encapsulating unit.

Here, according to an example embodiment of the present disclosure, the trench T may be provided so as to enclose the contact area between the first gate link line 140 and the second gate link line 145 where the plurality of first contact holes 170a and second contact holes 170b are formed.

Specifically, moisture may permeate the contact area between the gate link lines 140 and 145 in the non-active area NA between the bending area BA and the active area AA through the exposed organic film, such as a bank 115e, which may result in the corrosion defect. Further, during an operation experiment under an environment of a temperature of 65 degrees and a humidity of 95% to evaluate the reliability of the display panel, it was determined that the corrosion defect may be generated in the contact area. The corrosion defect may be caused because the organic films of the bank 115e and the planarization layers 115c and 115d are vulnerable to a moisture permeation path (see an arrow illustrated in FIG. 9) and may be deformed due to the moisture. Therefore, the adhesion with the first gate link line 140 may be weakened, and a wiring line having a low voltage, for example, the gate link line 140, may be corroded.

Therefore, an example embodiment of the present disclosure includes an organic film trench structure in which the organic film vulnerable to the moisture path is covered by an inorganic film of an interlayer insulating layer or a buffer layer of the touch panel. Even if the moisture path is formed through the exposed bank 115e above the contact area, the trench T enclosing the contact area may be formed so that the moisture does not permeate to the contact area. An upper portion of the bank 115e including the inside of the trench T may be covered by the inorganic film of the interlayer insulating layer 115h of the touch panel. Where the structure of the example embodiment of the present disclosure as described above was applied, the moisture permeation to the contact area was suppressed to suppress the corrosion defect in the evaluation of the reliability.

For example, the trench T may be formed by removing a partial area of the bank 115e and the planarization layers 115c and 115d around the plurality of first contact holes 170a and second contact holes 170b. Even though FIG. 8 illustrates that the trench T has a rectangular frame shape which encloses the plurality of first contact holes 170a and second contact holes 170b (in a plan view), it is not limited thereto. Therefore, any shape enclosing the plurality of first contact holes 170a and second contact holes 170b may be applicable. For example, the second gate link line 145 may be located in the trench T having a rectangular frame shape. Further, the plurality of first contact holes 170a and second contact holes 170b may be located in an area surrounded by the trench T having a rectangular frame shape (in a plan view as shown, e.g., in FIG. 8).

To this end, after the trench T is formed by removing a partial area of the first planarization layer 115c in which the first gate link line 140 is to be disposed, the first gate link line 140 may be disposed in the trench T and on the first planarization layer 115c. The first gate link line 140 may be deposited in the trench T with a predetermined thickness or deposited to fully fill the trench T in the first planarization layer 115c. Here, the first gate link line 140 may be bent downwardly in the portion where the trench T passes.

Further, the trench T may be formed to expose the second insulating layer 115b or be formed to remove only a part of the thickness of the first planarization layer 115c.

Further, after the first gate link line 140 is deposited in the trench T, the second planarization layer 115d and the bank 115e may be formed, and the trench T may be formed again to remove the second planarization layer 115d in the trench T. Thereafter, an interlayer insulating layer 115h of the touch panel having a predetermined thickness may be deposited on the first gate link line 140 in the trench T. However, the present disclosure is not limited thereto, and a buffer layer of the touch panel having a predetermined thickness may be deposited on the first gate link line 140 in the trench T.

The interlayer insulating layer 115h of the touch panel may be referred to as an inorganic insulating layer.

Further, a planarization layer 115i of the touch panel may be disposed on the interlayer insulating layer 115h of the touch panel. The planarization layer 115i of the touch panel may be referred to as an organic insulating layer.

The planarization layer 115i of the touch panel may extend to the bending area BA before the dam 180.

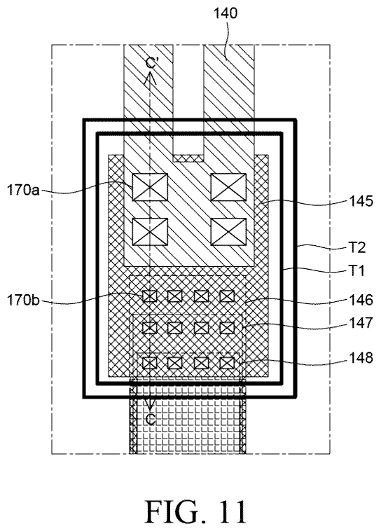

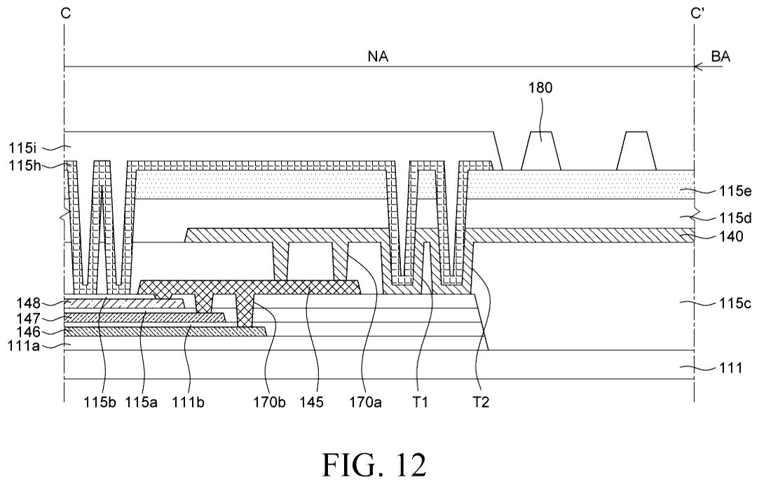

Also, the trench of the example embodiment of the present disclosure may be disposed in at least two layers, which will be described in detail with reference to FIGS. 11 and 12.

FIG. 11 is a plan view of a contact area of a flexible display device according to still another example embodiment of the present disclosure.

FIG. 12 is a cross-sectional view taken along the line C-C′ in FIG. 11.

Another example embodiment of the present disclosure shown in FIGS. 11 and 12 may have the substantially same configurations as the above-described example embodiment of FIGS. 7 to 10, except that double trenches T1 and T2 are configured. Thus, a redundant description may be omitted. The same configuration will be denoted with the same reference numeral. Here, the description for the same reference numerals may be provided above reference to FIGS. 1 to 10.

FIGS. 11 and 12 illustrate an example contact area between gate link lines 140 and 145 in a non-active area NA between a bending area BA and an active area AA of FIG. 3.

As shown in FIGS. 11 and 12, a first buffer layer 111a may be disposed on the substrate 111.

The first buffer layer 111a may extend to a part of the non-active area NA, without being disposed in the bending area BA.

A first signal line 146 may be disposed on the first buffer layer 111a.

For example, the first signal line 146 may be a gate routing line for transmitting a gate signal but is not limited thereto.

A second buffer layer 111b may be disposed on the first signal line 146.

The second buffer layer 111b may extend to a part of the non-active area NA, without being disposed in the bending area BA.

A second signal line 147 may be disposed on the second buffer layer 111b.

For example, the second signal line 147 may be a gate routing line for transmitting a gate signal but is not limited thereto.

The second signal line 147 may be disposed along the first signal line 146 above the first signal line 146 but is not limited thereto.

The first insulating layer 115a may be disposed on the second signal line 147.

The first insulating layer 115a may extend to a part of the non-active area NA, without being disposed in the bending area BA.

A third signal line 148 may be disposed on the first insulating layer 115a.

The third signal line 148 may be disposed on the same layer as the gate electrode of the active area but is not limited thereto.

For example, the third signal line 148 may be a gate routing line for transmitting a gate signal but is not limited thereto.

The third signal line 148 may be disposed along the first signal line 146 and the second signal line 147 above the first signal line 146 and the second signal line 147, but the present disclosure is not limited thereto.

The second insulating layer 115b may be disposed on the third signal line 148.

The second insulating layer 115b may extend to a part of the non-active area NA, without being disposed in the bending area BA.

A partial area of each of the second buffer layer 111b, the first insulating layer 115a, and the second insulating layer 115b may be removed to form a plurality of second contact holes 170b which respectively expose a part of the first signal line 146, a part of the second signal line 147, and a part of the third signal line 148. For example, a partial area of the second insulating layer 115b may be removed to form a second contact hole 170b which exposes a part of the third signal line 148. Further, a partial area of the first insulating layer 115a and the second insulating layer 115b may be removed to form another second contact hole 170b which exposes a part of the second signal line 147. Further, a partial area of the second buffer layer 111b, the first insulating layer 115a, and the second insulating layer 115b may be removed to form still another second contact hole 170b which exposes a part of the first signal line 146.

A second gate link line 145 may be disposed on the second insulating layer 115b.

The second gate link line 145 may be connected to the first signal line 146, the second signal line 147, and the third signal line 148, respectively through the plurality of second contact holes 170b.

The second gate link line 145 may overlap respective ends of the first signal line 146, the second signal line 147, and the third signal line 148.

The first planarization layer 115c may be disposed on the second gate link line 145 so as to cover the second buffer layer 111b, the first insulating layer 115a, the second insulating layer 115b, and the second gate link line 145.

The first planarization layer 115c may extend to the non-active area NA including the bending area BA. For example, in a part of the non-active area NA including the bending area BA, the first planarization layer 115c may be disposed on the substrate 111.

A partial area of the first planarization layer 115c may be removed to form a plurality of first contact holes 170a which expose a part of the second gate link line 145.

The first gate link line 140 may be disposed on the first planarization layer 115c.

For example, the first gate link line 140 may be connected to the second gate link line 145 through the plurality of first contact holes 170a.

For example, the first gate link line 140 may overlap one end of the second gate link line 145 and may extend to the bending area BA.

For example, the first gate link line 140 may be configured as double wiring lines but is not limited thereto.

The second planarization layer 115d may be disposed on the first gate link line 140 so as to cover the first gate link line 140.

The second planarization layer 115d may extend to the non-active area NA including the bending area BA.

The bank 115e may be disposed on the second planarization layer 115d.

The bank 115e may extend to the non-active area NA including the bending area BA.

A plurality of dams 180 may be disposed on the bank 115e in the non-active area NA in the vicinity of the bending area BA.

In addition, according to another example embodiment of the present disclosure, trenches T1 and T2 may be provided so as to enclose the contact area between the first gate link line 140 and the second gate link line 145 in which the plurality of first contact holes 170a and second contact holes 170b are formed.

According to another example embodiment of the present disclosure, double trenches including a first trench T1 at the inside and a second trench T2 at the outside may be disposed, but the present disclosure is not limited thereto. For example, triple or more trenches may be disposed.

As described above, the trenches T1 and T2 may be formed by removing a partial area of the bank 115e and the planarization layers 115c and 115d around the plurality of first contact holes 170a and second contact holes 170b. Even though FIG. 11 illustrates that the trenches T1 and T2 have a rectangular frame shape which encloses the plurality of first contact holes 170a and second contact holes 170b in a plan view, the present disclosure is not limited to the illustrated shape. Therefore, any shape enclosing the plurality of first contact holes 170a and second contact holes 170b may be applicable. For example, the second gate link line 145 may be located in the trenches T1 and T2 having a rectangular frame shape. Further, the plurality of first contact holes 170a and second contact holes 170b may be located in an area surrounded by the trenches T1 and T2 having a rectangular frame shape (in a plan view a shown, e.g., in FIG. 11).

For example, the first gate link line 140 may be disposed in the trenches T1 and T2 and on the first planarization layer 115c. The first gate link line 140 may be deposited in the trenches T1 and T2 with a predetermined thickness or be deposited to fully fill the trenches T1 and T2 in the first planarization layer 115c. Here, the first gate link line 140 may be bent downwardly in the portion where the trenches T1 and T2 pass.

Further, the trenches T1 and T2 may be formed to expose the second insulating layer 115b or be formed to remove only a part of the thickness of the first planarization layer 115c.

Thereafter, an interlayer insulating layer 115h of the touch panel having a predetermined thickness may be deposited on the first gate link line 140 in the trenches T1 and T2.

Further, a planarization layer 115i of the touch panel may be disposed on the interlayer insulating layer 115h of the touch panel.

The planarization layer 115i of the touch panel may extend to the bending area BA before the dam 180.

As described above, according to another example embodiment of the present disclosure, double trenches T1 and T2 having a rectangular frame shape (in a plan view as shown, e.g., in FIG. 11) may be disposed so as to enclose the contact area in which the plurality of first contact holes 170a and second contact holes 170b are disposed. Accordingly, even if a moisture path is formed through the exposed bank 115e above the contact area, the moisture may be more surely blocked from permeating to the contact area.

Various example embodiments of the present disclosure can also be described as follows:

According to an aspect of the present disclosure, a flexible display device may include: a substrate including an active area and a non-active area, the non-active area including a driving circuit, a bending area, and a contact area between the driving circuit and the bending area; a plurality of signal lines on the substrate and extending between the driving circuit and the contact area; a first gate link line disposed above the plurality of signal lines in the contact area, the first gate link line being connected to each of the plurality of signal lines respectively through a plurality of first contact holes; a first planarization layer on the first gate link line; a second gate link line on the first planarization layer and connected to the first gate link line through at least one second contact hole; a second planarization layer and a bank on the second gate link line; and a trench penetrating at least the bank, the trench enclosing the plurality of first contact holes, at least one second contact hole, and the second gate link line in a plan view.

The plurality of signal lines may include a first signal line on a first buffer layer on the substrate and a second signal line on a second buffer layer on the first signal line. The second signal line may be disposed above the first signal line.

The plurality of signal lines may further include a third signal line on a first insulating layer on the second signal line. The third signal line may be disposed above the first signal line and the second signal line.

The first buffer layer, the second buffer layer, and the first insulating layer may be disposed in the non-active area outside the bending area.

The flexible display device may further include a second insulating layer on the third signal line. The plurality of first contact holes may penetrate one or more of the second buffer layer, the first insulating layer, and the second insulating layer to expose parts of the first signal line, the second signal line, and the third signal line, respectively.

The first gate link line may overlap an end of each of the first signal line, the second signal line, and the third signal line.

The flexible display device may further include an inorganic insulating layer on the bank and in the trench and an organic insulating layer on the inorganic insulating layer.

The first planarization layer and the second planarization layer may be disposed in the contact area and may extend to the bending area.

The at least one second contact hole may penetrate the first planarization layer to expose a part of the first gate link line.

The second gate link line may overlap an end of the first gate link line and may extend to the bending area.

The trench may penetrate the bank, the second planarization layer, and the first planarization layer in the contact area.

The second gate link line may be disposed in the trench and on the first planarization layer.

The second gate link line may be disposed in the trench with a predetermined thickness or may fully fill a portion of the trench penetrating the first planarization layer.

The flexible display device may further include an inorganic insulating layer on the second gate link line in the trench, the inorganic insulating layer having a predetermined thickness in the trench.

The first gate link line may be bent downwardly into the trench at a portion where the trench penetrates the first planarization layer.

The trench may have a rectangular frame shape enclosing the plurality of first contact holes and the at least one second contact hole in the plan view.

The flexible display device may further include another trench penetrating at least the bank and surrounding the trench in the plan view.

According to another aspect of the present disclosure, a flexible display device may include: a substrate including an active area and a non-active area including a bending area; a first gate link line disposed above the substrate in the non-active area including in the bending area; a second gate link line disposed below the first gate link line and connected to the first gate link line through at least one first contact hole in the non-active area outside the bending area; a plurality of signal lines disposed below the second gate link line and connected to the second gate link line respectively through a plurality of second contact holes in the non-active area outside the bending area; a trench disposed in the non-active area and enclosing the at least one first contact hole, the plurality of second contact holes, and the second gate link line in a plan view; and an inorganic insulating layer disposed in the trench.

The flexible display device may further include a planarization layer between the first gate link line and the substrate. The trench may penetrate the planarization layer, and the first gate link line may be disposed in the trench.

The inorganic insulating layer may be disposed with a predetermined thickness on the first gate link line in the trench.

It will be apparent to those skilled in the art that the present disclosure is not limited by the above-described example embodiments and the accompanying drawings, and that various substitutions, modifications, and variations can be made in the present disclosure without departing from the spirit or scope of the disclosures. Therefore, the above example embodiments of the present disclosure are provided for illustrative purposes and are not intended to limit the scope or technical concept of the present disclosure. The protective scope of the present disclosure should be construed based on the following claims and their equivalents, and it is intended that the present disclosure cover all modifications and variations of this disclosure that come within the scope of the claims and their equivalents.

What is claimed is:

1. A flexible display device, comprising:
a substrate including an active area and a non-active area, the non-active area including a driving circuit, a bending area, and a contact area between the driving circuit and the bending area;
a plurality of signal lines on the substrate and extending between the driving circuit and the contact area;
a first gate link line disposed above the plurality of signal lines in the contact area, the first gate link line being connected to each of the plurality of signal lines respectively through a plurality of first contact holes;
a first planarization layer on the first gate link line;
a second gate link line on the first planarization layer and connected to the first gate link line through at least one second contact hole;
a second planarization layer and a bank on the second gate link line; and
a trench penetrating at least the bank, the trench enclosing the plurality of first contact holes, at least one second contact hole, and the second gate link line in a plan view.

2. The flexible display device of claim 1, wherein the plurality of signal lines include:
a first signal line on a first buffer layer on the substrate; and
a second signal line on a second buffer layer on the first signal line,
wherein the second signal line is disposed above the first signal line.

3. The flexible display device of claim 2, wherein:
the plurality of signal lines further include a third signal line on a first insulating layer on the second signal line; and
the third signal line is disposed above the first signal line and the second signal line.

4. The flexible display device of claim 3, wherein the first buffer layer, the second buffer layer, and the first insulating layer are disposed in the non-active area outside the bending area.

5. The flexible display device of claim 3, further comprising:
a second insulating layer on the third signal line,
wherein the plurality of first contact holes penetrate one or more of the second buffer layer, the first insulating layer, and the second insulating layer to expose parts of the first signal line, the second signal line, and the third signal line, respectively.

6. The flexible display device of claim 3, wherein the first gate link line overlaps an end of each of the first signal line, the second signal line, and the third signal line.

7. The flexible display device of claim 1, further comprising:
an inorganic insulating layer on the bank and in the trench; and
an organic insulating layer on the inorganic insulating layer.

8. The flexible display device of claim 1, wherein the first planarization layer and the second planarization layer are disposed in the contact area and extend to the bending area.

9. The flexible display device of claim 1, wherein the at least one second contact hole penetrates the first planarization layer to expose a part of the first gate link line.

10. The flexible display device of claim 1, wherein the second gate link line overlaps an end of the first gate link line and extends to the bending area.

11. The flexible display device of claim 1, wherein the trench penetrates the bank, the second planarization layer, and the first planarization layer in the contact area.

12. The flexible display device of claim 11, wherein the second gate link line is disposed in the trench and on the first planarization layer.

13. The flexible display device of claim 12, wherein:
the second gate link line is disposed in the trench with a predetermined thickness, or
the second gate link line fully fills a portion of the trench penetrating the first planarization layer.

14. The flexible display device of claim 12, further comprising:
an inorganic insulating layer on the second gate link line in the trench, the inorganic insulating layer having a predetermined thickness in the trench.

15. The flexible display device of claim 12, wherein the first gate link line is bent downwardly into the trench at a portion where the trench penetrates the first planarization layer.

16. The flexible display device of claim 1, wherein the trench has a rectangular frame shape enclosing the plurality of first contact holes and the at least one second contact hole in the plan view.

17. The flexible display device of claim 1, further comprising another trench penetrating at least the bank and surrounding the trench in the plan view.

18. A flexible display device, comprising:
a substrate including an active area and a non-active area including a bending area;
a first gate link line disposed above the substrate in the non-active area including in the bending area;
a second gate link line disposed below the first gate link line and connected to the first gate link line through at least one first contact hole in the non-active area outside the bending area;
a plurality of signal lines disposed below the second gate link line and connected to the second gate link line respectively through a plurality of second contact holes in the non-active area outside the bending area;
a trench disposed in the non-active area and enclosing the at least one first contact hole, the plurality of second contact holes, and the second gate link line in a plan view; and
an inorganic insulating layer disposed in the trench.

19. The flexible display device of claim 18, further comprising:
a planarization layer between the first gate link line and the substrate,
wherein the trench penetrates the planarization layer, and the first gate link line is disposed in the trench.

20. The flexible display device of claim 19, wherein the inorganic insulating layer is disposed with a predetermined thickness on the first gate link line in the trench.
